(19) United States
(12) Patent Application Publication
(10) Pub. No.: US 2002/0083581 A1
(43) Pub. Date: Jul. 4, 2002

(54) Defective circuit scanning device and method

(75) Inventor: Robert Huber, Duluth, GA (US)

Correspondence Address: Siemens Corporation, Intellectual Property Department, 186 Wood Avenue South, Iselin, NJ, 08830, US

(73) Assignee: Siemens Energy & Automation, Inc.

(21) Appl. No.: 10/052,428

(22) Filed: Jan. 18, 2002

Related U.S. Application Data
(62) Division of application No. 09/716,019, filed on Nov. 17, 2000.
(60) Provisional application No. 60/225,427, filed on Aug. 15, 2000.

(51) Int. Cl. B23P 19/00; H05K 3/30

(52) U.S. Cl. 29/740; 29/739; 29/832

(57) ABSTRACT

A device for processing multi-up panels includes a bad mark scanner for reading a surface of a multi-up panel and a processor receiving at least one input from the scanner for determining a bad mark on the multi-up panel. Also provided is circuit panel manufacturing assembly line having a circuit panel bad mark scanner, a panel component placement machine separate from the scanner, and a panel conveyor located at least between the circuit panel scanner and the panel component placement machine for conveying the panels. Further provided is a method for determining bad marks on multi-up panels comprising the steps of scanning a multi-up panel with a scanner so as to form scan data and determining a bad mark on the multi-up panel as a function of the scan data.

### REFERENCE TO RELATED APPLICATION AND PRIORITY CLAIM

The present application claims priority from U.S. Provisional Patent Application No. 60/225,427 filed on Aug. 15, 2000, which application is hereby incorporated by reference herein.

### BACKGROUND OF THE INVENTION

1. Field of the Invention

The present invention relates generally to printed circuit boards and more particularly to a device and method for recognizing defective circuits on multiple circuit panels.

2. Background Information

In the electronics industry, a trend toward miniaturization has led to smaller and smaller circuit boards, which are used in a wide variety of products such as cellular telephones, automobiles and appliances. From a manufacturing standpoint, it has become desirable for several printed circuits to be placed together on a single panel, with the panel then being separated at the end of the manufacturing process into individual printed circuit boards. The circuits on the panel thus are not electrically connected to one another on the panel. Such panels with multiple individual circuits are known as multi-up panels, and may include more than a hundred individual circuits. U.S. Pat. No. 5,528,826, for example, purports to disclose a method for constructing a high-yield multi-up panel.

The panels, once constructed, are sent through processing devices, such as placement equipment (also known as pick-and-place devices) that places components such as capacitors onto the printed circuit. There may be several different processing devices in the manufacturing line for the panel. At the end of the manufacturing line, the panel is separated into individual completed circuit boards.

Despite attempts to increase yields and lower the error rates of circuits on panels, bad or defective circuits still result in many panels. However, even if one or more defective circuits are present on a single panel, it often is still desirable to process the other non-defective circuits so that the entire panel need not be discarded.

If upon inspection of a panel a bad circuit is found, a bad mark or inkspot typically will mark the defective circuit. The bad mark may be placed by an inspector, for example, on the panel, and can be placed directly next to or on the circuit.

As the panel travels through the line, each placement machine in the line may view the circuits with a camera, which is used to identify fiducials and other panel information. The camera thus also is used to determine the location of any bad marks using an optical recognition algorithm. If a bad mark is found, the placement machine does not place components on the defective circuits.

The reading for bad marks by placement equipment can be time-consuming, often on the order of 0.5 to 1.0 seconds to locate a bad mark on a circuit. Reading of a multi-up panel with 100 circuits thus may take 50 to 100 seconds for each panel for each placement machine. On a high volume line with several placement machines, the bad mark recognition time might even exceed the processing time.

In order to address the problem of each placement machine in a line having to read the bad marks, Siemens Energy and Automation, Inc. of Georgia has used a method in which only the first placement machine reads the panel for bad marks, and then transmits the bad mark information for the panel to other placement machines in the line. However, even this method requires that the first placement machine spend a large amount of time on each panel to determine bad marks. Moreover, bad mark data in an easily readable form is not located directly on the panel. In addition, placement machines are expensive, high volume modules often costing up to a million dollars.

Scanners, which have a linear array of photodiodes, are used to digitize surface information of printed circuit boards. ScanCAD International of Morrison, Colo. sells various flatbed scanners to convert printed circuit boards into digital information, such as Gerber files. ScanCAD also sells a scanner which inspects glue dots for PC-boards, with the scanner being mounted above a conveyor on which the PC-boards travel. These scanners however have not been used for reading bad marks on multi-up panels.

U.S. Pat. No. 6,049,740 purports to disclose a scanner for scanning a printed circuit board with no defects and scanning a printed circuit board having potential defects. The two scans are then compared. This method and device requires a high-quality scan to image the circuit boards properly. The time for such scans is extensive. Furthermore, no scan of a multi-up panel or bad marks is disclosed.

### BRIEF SUMMARY OF THE INVENTION

An object of the present invention is to improve the throughput of multi-up panel manufacturing lines. An additional or alternative object of the present invention is to provide a method and device for cost-effective identification of bad marks on multi-up panels.

The present invention provides a device for processing multi-up panels comprising:

a bad mark scanner for reading a surface of a multi-up panel; and

a processor receiving at least one input from the scanner for determining a bad mark on the multi-up panel.

By using a bad mark scanner, which can image the panels at a faster rate than the cameras and optical recognition systems of placement machines, the speed of identifying defective circuits on the multi-up panels can be increased.

The scanner preferably is a scanner of a type commercially-available from ScanCAD International of Morrison, Colo., and may recognize bad marks similar to that used to identify glue spots. The software for the processor may, for example, determine that when a certain percentage of a scanned area is consistently dark, that a bad mark is present.

Because only the bad marks must be determined, the bad mark scanner need not be of high quality. Preferably, the scan resolution is less than 300×300 dots per square inch. Depending on the type of marks and panels used, a scan with a resolution of approximately 100×100 dots per square inch, or with even lower resolution, may be used. This quality of scan can be performed quickly.

Preferably, the device includes a conveyor for transporting the multi-up panels, the conveyor having a direction of travel, and the scanner includes a linear array of photodiodes located above the conveyor, the array being arranged perpendicular to the direction of travel.

The device may further include a bar code reader for reading bar code information of a multi-up panel, so that bad mark information can be stored and associated with the bar code information.

The device preferably is part of an assembly line which includes at least one placement machine for placing at least one component on the multi-up panel, the placement machine being located downstream from the scanner and receiving at least one input from the processor. Most preferably, a plurality of placement machines are located downstream from the scanner.

With the present device, the placement machines of the assembly line can receive input from the processor as to which circuits on a panel are defective. The placement machines thus do not place components on those circuits. All the placement machines of the assembly line can refrain from determining the presence of bad marks, thereby speeding up the processing time for the panels.

Each of the placement machines preferably has a bar code reader, which reads bar code information from the panels. The bar code information from the panel is matched to bar code and bad mark data provided by the processor. Proper bad mark data thus can be applied with a high reliability to the proper panel.

The present invention also provides a circuit panel manufacturing assembly line comprising:

a circuit panel bad mark scanner;

a panel component placement machine; and

a panel conveyor located at least between the circuit panel scanner and the panel component placement machine for conveying the panels.

By having a separate scanner located apart from the component placement machine, the camera and imaging equipment of the component placement machine does not need to identify bad marks. Processing of the circuit panels can proceed at a faster pace.

The scanner outputs output data for permitting a processor to determining a bad mark on the circuit panel. Preferably the output data includes both bad mark scan information and bar code scan information read from a bar code on the panel.

The placement machine receives input data as a function of the output data. This input data preferably includes the bar code information and the bad mark scan information.

The bar code information for example identifies a multi-up panel and relates that panel to database information. For example, a relational database, such as those sold by the Oracle Corporation or Microsoft Corporation, can be provided so that each panel identifier is stored relationally to data identifying the number of circuits on the multi-up panel, the size of the circuits and/or the location of the circuits on the panel. For example, a multi-up panel might have 42 circuits in a 6 by 7 pattern. The database then provides a database with an identifier for each of the 42 circuits and the location of each circuit on the panel. Other information related to the circuits can also be stored in the database.

The processor can receive the bad mark scan information and determine the location of the bad mark scan and identify, using the database information, which of the circuits has a bad mark.

The scanner preferably is a stationary line scanner, and the processor preferably can receive conveyor speed information. With a stationary line scanner, the scanning starts as the front edge of the panel passes the line scanner. Lines of the panel of a particular depth (depending on the type of diodes used) are scanned as the panel moves past the line scanner. Scan data corresponding to the entire panel is thus obtained, with the location of bad marks being identified by, for example, the presence of a dark, homogenous region.

The scanner preferably is one manufactured by ScanCAD International of Morrison, Colo., and the algorithm for identifying bad marks similar to ones used ScanCAD International scanners to inspect and identify glue dots on PC boards.

The scan data preferably is then correlated with the database information so that the actual bad circuits on the multi-up panel are identified, preferably by number. This bad mark data preferably is stored along with the bar code identification information and sent to all assembly machines, include all placement machines on the line.

The processor, bad mark scanner and placement machines preferably are connected with a LAN, for example running on a 10/100 Ethernet. The data may be transferred in a bad mark protocol, which for example includes 6 bits for the bar code identification for the multi-up panel, followed by a string of numbers identifying the bad mark circuits for that multi-up panel.

The present invention also provides a method for determining bad marks on multi-up panels comprising the steps of

scanning a multi-up panel with a scanner so as to form scan data; and

determining a bad mark on the multi-up panel as a function of the scan data.

Preferably, the method further includes scanning a bar code on the multi-up panel.

The method may further including transmitting bad mark data to at least one placement machine, and preferably to more than one placement machine.

The bad mark data may be transmitted via a wireless or land-based communications network.

The method may also include transmitting the bad mark data to a separator.

Preferably, the scanning step includes line scanning the multi-up panel and the method further includes conveying the panel on a conveyor belt.

### BRIEF DESCRIPTION OF THE DRAWINGS

A preferred embodiment of the present invention is described below by reference to the following drawings, in which:

FIG. 1 shows a side view of an assembly line for multi-up panels according to the present invention;

FIG. 2 shows a top view of a multi-up panel with bad marks on two circuits, the panel having a bar code; and

FIG. 3 shows a flowchart of a preferred method of the present invention.

### DETAILED DESCRIPTION

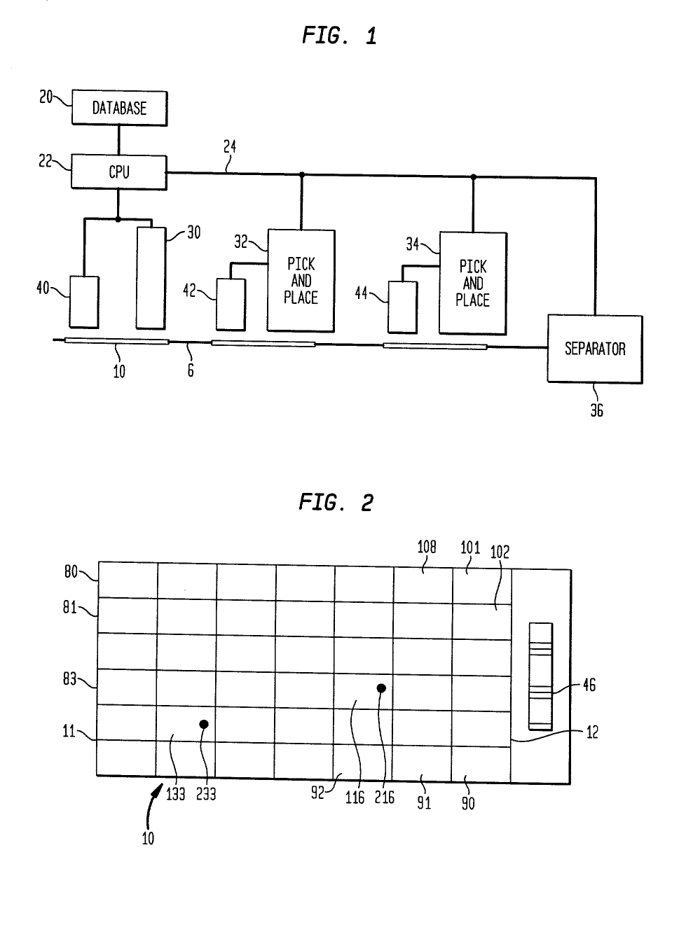

FIG. 1 shows an multi-up panel assembly line according to the present invention. A multi-up panel 10 travels along a conveyor belt 6 toward a separator 36, which separates the panel 10 into individual circuit boards.

As shown in top view in FIG. 2, panel 10 includes a bar code area 46, preferably at a front of the board, and a plurality of circuits identified schematically by the grid on panel 10. The circuits may be, for example, numerically identified, so that the circuit 101 in a first column 80 and first row 90 is identified as the first circuit. The circuit 102 in a second column 82 and first row 90 may be identified as the second circuit. The second row 91, beginning with circuit 108 may then contain circuits eight through thirteen, and so on, so that all forty-two circuits shown are identified by a number. As the panel has a known size, and the circuits also have a known size, the location for each circuit extending between a front circuit area edge 12 and a read circuit area edge 11 is also known. The location of each circuit may be stored for example as a set of points, for example four, two-dimensional points if the circuits are generally rectangular in shape.

In the example shown in FIG. 2, the sixteenth circuit 116 and the thirty-third circuit 133 have defects, and thus are marked by bad marks 216 and 233, respectively. The bad marks are, for example, ink marks placed in a predefined area of the circuit by a quality control machine or employee. The predefined area may be for example a blank area in the forward middle section of the space on the panel assigned to the circuit.

As shown in FIG. 1 and with reference to the panel 110 in FIG. 2, the panel 110 travels on conveyor belt 6 past a bar code scanner 40, which reads bar code 46 on panel 110. The bar code information is fed to a processor 22, for example one commercially available from the Intel Corporation such as a PENTIUM III processor. A database 20 can be accessed by processor 22, so as to provide information relating to panel 10 as a function of the bar code information. The location and numbering of the circuits, stored in database 20 for each panel, is thus provided to the processor 22 for panel 10, for example through an SQL-based query of database 20 using the bar code information.

The lead circuit edge 12 of panel 10 passes by a bad mark scanner 30, which may be for example a line scanner having a linear array of photodiodes. The scanner may be a modification of a scanner commercially available from ScanCAD International for reading glue dots on PC boards. Depending on the size of the bad marks used, the scanner can operate at resolutions of 300×300 dots per square inch or less. The scanner 30 provides data for each row of circuits as the circuits pass under the scanner 30. An algorithm in processor 22 can identify if a dark homogenous mark is located in a bad mark area at the front of each circuit, and identifies where the mark is located in the row. The algorithm can be run quickly by the processor, as a location of a bad mark in a row can be quickly correlated with the circuit location data stored in database 20.

The scanning of a single circuit area to identify a bad mark may proceed on the order of 100 milliseconds or even quicker depending on the number of circuits per multi-up panel, scan resolution, mark quality and algorithm efficiency. The bad mark scanner is also price advantageous, typically costing under $100,000. Placement equipment used to identify bad marks on the other hand typically have longer bad mark identification times due to the more complicated optics involved, and are typically more expensive.

While a line scanner has been discussed specifically, a flatbed scanner of the type available from ScanCAD International could also be used to identify the bad marks. The panel 10 could be stopped shortly on conveyor belt 6 to allow for such flatbed scanning. Moreover, more than a single linear array of photodiodes could be provided so as to increase the scanning speed of the scanner 30. Additional scanners could also be provided to increase throughput.

As panel 10 passes under scanner 30, processor 22 identifies bad marks 216 and 233 as rows 90, 91, 92, etc. pass under the scanner 30. Since the edge 12 and conveyor belt 6 speed are known, the exact row being scanned may be determined.

For example, as row 92 passes under scanner 30, a bad mark 216 is identified at a certain location in the line scan data, which location can be correlated with a fourth column 83 of the panel. Since the row and column data are known, bad mark 216 can be correlated with circuit number 116 by processor 20. The scanner also can scan intermittently, so that only the front or bad mark area of each row 90, 91 is scanned, thus also increasing throughput.

The bad mark data for panel 10 can then be stored in database 20, or simply transmitted along with the bar code information via a LAN 24 to placement machines 32 and 34, which place components on the circuits of panel 10. Placement machines 32 and 34 may have their own processing devices. As panel 10 reaches placement machine 32, bar code 46 is scanned by a bar code reader 42 and the placement machine 32 processor determined that the circuits 116 and 133 are defective. Components thus are not placed on those circuits. Alternatively, processor 22 controls the placement machines 32 and 34 via LAN 24, so that bar code reader 42 sends information to processor 22, which then sends control signals to placement machine 32. A bar code reader 44 is assigned to second placement machine 34. If second placement machine 34 is the last placement device before separator 36, bar code reader 44 can also function as the bar code reader for separator 36. Alternatively, separator 36 could have a bar code reader as well.

Once the components have been placed on non-defective circuits of panel 10, panel 10 is separated in separator 36 so that the non-defective circuit boards are delivered at an exit. Defective circuits can be placed in a recycle bin.

The processor, database and placement machines may also be linked over a WAN, through wireless technology or through a global communications network, such as the Internet, rather than the LAN shown. The bad mark information advantageously thus could occur at a bad mark scanning station located directly at a quality control unit. The bad mark scanning thus could occur completely separately from the assembly line, with the bad mark data being stored in the database until needed to be accessed by the placement machines 32 and 34.

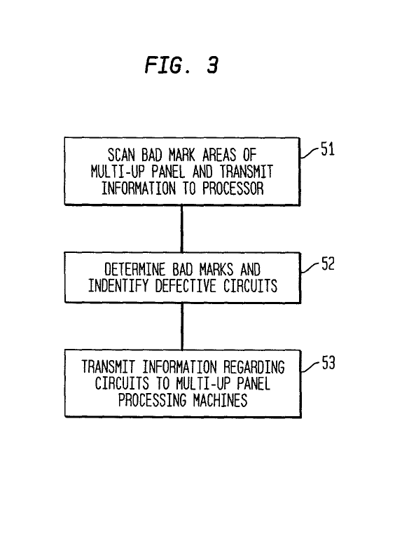

FIG. 3 shows a flowchart of a preferred method of the present invention. In step 51, the bad marks areas of a multi-up panel, for example the front part of the circuit rows, are scanned. In step 52 the processor determines the presence of a bad mark and, as a function of database information, identifies which circuits, if any, are defective. In step 53, the defective circuits are identified to at least one multi-up panel processing device, such as a separator or placement machine.

A Processor 22 as defined herein can include any type of data processing device, including a microprocessor or a programmable logic controller.

What is claimed is:

1. A device for processing multi-up panels comprising:
a bad mark scanner for reading a surface of a multi-up panel; and
a processor receiving at least one input from the scanner for determining a bad mark on the multi-up panel.

2. The device as recited in claim 1 wherein the bad mark scanner is located on an assembly line upstream from a placement machine, the placement machine receiving an input from the processor.

3. The device as recited in claim 2 further comprising a conveyor for transporting the multi-up panel between the bad mark scanner and the placement machine.

4. The device as recited in claim 1 wherein the scanner is a line scanner.

5. The device as recited in claim 1 further comprising a bar code reader for reading bar code information of the multi-up panel.

6. The device as recited in claim 1 further comprising a database for storing information related to circuits on the multi-up panel, the database accessible by the processor.

7. The device as recited in claim 1 wherein the bad mark scanner is located on an assembly line upstream from at least one multi-up panel processing machine for placing at least one component on the multi-up panel, the at least one multi-up panel processing machine receiving at least one input from the processor.

8. The device as recited in claim 7 wherein the at least one processing machine includes a plurality of placement machines located downstream from the scanner.

9. The device as recited in claim 7 further comprising a bar code reader assigned to the at least one processing machine.

10. The device as recited in claim 7 further comprising a LAN connecting the at least one processing device and the processor.

11. The device as recited in claim 1 wherein the scanner has a resolution of 300×300 dots per square inch or fewer.

12. A circuit panel manufacturing assembly line comprising:
a circuit panel bad mark scanner;
a panel component placement machine separate from the scanner; and
a panel conveyor located at least between the circuit panel scanner and the panel component placement machine for conveying the panels.

13. The circuit panel manufacturing assembly line as recited in claim 12 wherein the scanner is a line scanner.

14. The circuit panel manufacturing assembly line as recited in claim 12 further comprising a second component placement machine located next to the conveyor.

15. The circuit panel manufacturing assembly line as recited in claim 12 further comprising a bar code reader located next to the conveyor.

16. The circuit panel manufacturing assembly line as recited in claim 12 further comprising a bar code reader located between the scanner and the placement machine.

17. The circuit panel manufacturing assembly line as recited in claim 12 further comprising a processor connected to the scanner and the placement machine.

18. The circuit panel manufacturing assembly line as recited in claim 12 wherein the scanner is a stationary line scanner.

19. The circuit panel manufacturing assembly line as recited in claim 12 further comprising a communications network connecting the scanner and the placement machine.

20. The circuit panel manufacturing assembly line as recited in claim 19 wherein the communications network is a LAN.

21. The circuit panel manufacturing assembly line as recited in claim 19 wherein the communications network is a wireless network.

22. The circuit panel manufacturing assembly line as recited in claim 19 wherein the communications network is a WAN.

23. The circuit panel manufacturing assembly line as recited in claim 19 wherein the communications network is a global information network.

24. A method for determining bad marks on multi-up panels comprising the steps of:
scanning a multi-up panel with a scanner so as to form scan data; and
determining a bad mark on the multi-up panel as a function of the scan data.

25. The method as recited in claim 24 further comprising scanning a bar code on the multi-up panel.

26. The method as recited in claim 24 further comprising transmitting bad mark data to at least one placement machine.

27. The method as recited in claim 26 wherein the bad mark data is transmitted over a LAN.

28. The method as recited in claim 26 wherein the bad mark data is transmitted over a global communication network.

29. The method as recited in claim 24 wherein the scanning step includes line scanning the multi-up panel.

30. The method as recited in claim 24 further comprising conveying the panel on a conveyor belt.

31. The method as recited in claim 24 wherein the scanning step occurs at a resolution of or below 300×300 dots per square inch.

32. A multi-up panel comprising a plurality of circuits, each circuit having a bad mark area for application of a bad mark, the multi-up panel being processed with the method of claim 24.
